(19) United States
(12) Patent Application Publication
(10) Pub. No.: US 2026/0059774 A1
(43) Pub. Date: Feb. 26, 2026

(54) CHIP WITH METAL-OXIDE-METAL CAPACITOR

(71) Applicant: Shanghai Huali Integrated Circuit Corporation, Shanghai (CN)

(72) Inventors: Zhi Tian, Shanghai (CN); Haoyu Chen, Shanghai (CN); Hua Shao, Shanghai (CN)

(73) Assignee: Shanghai Huali Integrated Circuit Corporation, Shanghai (CN)

(21) Appl. No.: 19/188,239

(22) Filed: Apr. 24, 2025

(30) Foreign Application Priority Data
Aug. 26, 2024 (CN) 202411180355.3

(51) Int. Cl. H10D 1/62; H10D 62/10; H10D 64/23; H10D 64/60; H10D 86/40; H10D 86/60; H10K 59/121; H10K 59/88

(52) U.S. Cl. CPC H10D 1/62; H10D 62/102; H10D 64/23; H10D 64/60; H10D 86/481; H10D 86/60; H10K 59/1216; H10K 59/88

(57) ABSTRACT

The present application discloses a chip with a metal-oxide-metal capacitor, including at least two metal capacitor areas with the same requirement for functions and capacitances. For each metal capacitor area, a gate oxide layer, a gate metal layer, a high-resistance layer and a capacitor metal layer are sequentially formed on an active area of a substrate from bottom to top. Vertical projections of the active area, the gate oxide layer and the gate metal layer are located within a vertical projection of the high-resistance layer. Insulating dielectric layers are formed between the high-resistance layer and the gate metal layer and between the high-resistance layer and the capacitor metal layer, respectively. A metal capacitor in the chip with the metal-oxide-metal capacitor of the present application has good repeatability. Moreover, the uniformity of parasitic capacitors when a high voltage is applied to the metal-oxide-metal capacitor is improved.

### CROSS-REFERENCE TO RELATED APPLICATIONS

This application claims priority to Chinese patent application No. 202411180355.3, filed on Aug. 26, 2024, the disclosure of which is incorporated herein by reference in its entirety.

### TECHNICAL FIELD

The present application relates to semiconductor technology, and in particular, to a chip with a metal-oxide-metal (MOM) capacitor.

### BACKGROUND

An OLED (organic light emitting diode) as a third generation of display technology is of a current injection composite light emitting type with main advantages of high brightness, high contrast, large viewing angle, high response speed, low operating voltage, strong adaptability, high energy conversion efficiency, simple production process and the like. Due to huge technical advantages and application prospects of the OLED, the OLED has received extensive attention from bottom academia and industry.

The OLED is of a current drive type. The higher a current of the OLED is, the greater the brightness is. However, the current will decay over time, resulting in a corresponding decrease in brightness, as shown in FIG. 1a to FIG. 1c. FIG. 1a shows a current density-brightness curve of a white OLED, wherein higher the current is, the greater the brightness is. FIG. 1b shows a degradation curve of a current of a white OLED over time wherein a drive current decreases over time. FIG. 1c shows a conventional drive current compensation circuit of a white OLED, wherein a capacitor C will use a metal-oxide-metal (MOM) capacitor. This is mainly due to the presence of some leakage in the circuit over time. This is mainly due to the presence of some leakage in the drive circuit over time.

Generally, the problem of the corresponding decrease of the brightness corresponding to the current of the OLED over time due to some leakage in the drive circuit over time is solved by employing the compensation circuit. However, since the compensation circuit uses a capacitor, resulting in a certain difference in itself, the compensation circuit can only solve the problem caused by some leakage. With the demand for miniaturization, a capacitor device in the compensation circuit in the drive circuit extensively uses the metal-oxide-metal capacitor to save a space. Such a metal-oxide-metal (MOM) capacitor is formed by using the thickness of metal layers and the distance between the metal layers. As shown in FIG. 2a which is a schematic diagram of a stack of a plurality of layers of metal, a plurality of left-finger metal strips 151 and a plurality of right-finger metal strips 152 of the same layer of metal are interdigitated. The plurality of left-finger metal strips 151 are shorted and the plurality of right-finger metal strips 152 are connected to a substrate. FIG. 2b is a schematic diagram of the same layer of metal-oxide-metal capacitor. Ctotal=n*Cm*f, n is a number of layers of metal, and f is a number of fingers of each layer.

Generally, due to lower density of such a metal-oxide-metal (MOM) capacitor, a larger area (more than 5 μm*5 μm for a single size) is required. For an area below the metal-oxide-metal (MOM) capacitor, in order to ensure the chemical-mechanical grinding uniformity of an active area and a metal gate, a dummy pattern area is inserted in the active area and the metal gate, and a low end of the metal-oxide-metal (MOM) capacitor of the dummy pattern area is generally connected to a P-type substrate under the dummy pattern area. The dummy pattern area of the active area under the metal-oxide-metal (MOM) capacitor may have certain parasitic capacitors at high voltage. At present, in a 28 nm display driver, the metal-oxide-metal (MOM) capacitor works in a medium-voltage area (MV) and the corresponding gate silicon oxide thickness of the metal-oxide-metal (MOM) capacitor is between 18 nm and 22 nm. There will be parasitic capacitors when a voltage is applied to a first layer of metal of the metal-oxide-metal capacitor, which affects the uniformity of the capacitor having the same circuit function, and thus affects the performance of the drive current compensation circuit. FIG. 3a shows situation of a dummy pattern area of an existing metal capacitor area, with each area with the same requirements for functions and capacitances being different due to the difference in surrounding conditions. As shown in FIG. 3b, parasitic capacitors (Cp1, Cp2) will be greatly different, and the non-uniformity of capacitances of the parasitic capacitors will lead to some degradation of the performance of the OLED (organic light emitting diode).

### BRIEF SUMMARY

A technical problem to be solved by the present application is to provide a chip with a metal-oxide-metal (MOM) capacitor. A metal capacitor in the chip has a good repeatability. Moreover, the uniformity of parasitic capacitors when a high voltage is applied to the metal-oxide-metal (MOM) capacitor is improved.

To solve the technical problem mentioned above, the present application provides the chip with the metal-oxide-metal (MOM) capacitor, including at least two metal capacitor areas with the same requirements for functions and capacitances;

for each metal capacitor area, a gate oxide layer 12, a gate metal layer 13, a high-resistance layer 14 and a capacitor metal layer 15 are sequentially formed on an active area 11 of a substrate from bottom to top; vertical projections of the active area 11, the gate oxide layer 12 and the gate metal layer 13 are located within a vertical projection of the high-resistance layer 14; and insulating dielectric layers are formed between the high-resistance layer 14 and the gate metal layer 13 and between the high-resistance layer 14 and the capacitor metal layer 15, respectively;

the resistivity of the high-resistance layer 14 is greater than that of the gate metal layer 13;

the resistivity of the high-resistance layer 14 is greater than that of the capacitor metal layer 15.

Preferably, the gate oxide layer 12 is silicon oxide.

Preferably, the chip is an OLED driver chip.

Preferably, the OLED driver chip is fabricated by using a 28 nm high-voltage process platform.

Preferably, the capacitor metal layer 15 includes at least one layer of metal stacked sequentially from top to bottom and insulated from each other;

each layer of metal of the capacitor metal layer 15 includes a plurality of left-finger metal strips 151 and a plurality of right-finger metal strips 152; and

the plurality of left-finger metal strips 151 and the plurality of right-finger metal strips 152 are interdigitated, left ends of the left-finger metal strips 151 are shorted together, and right ends of the right-finger metal strips 152 are shorted together for connecting the substrate.

Preferably, the capacitor metal layers 15 of the metal capacitor areas having the same capacitances are connected in parallel.

Preferably, the gate metal layer 13 is aluminum.

Preferably, the capacitor metal layer 13 is copper.

Preferably, the high-resistance layer 14 is polysilicon.

Preferably, the high-resistance layer 14 is P-doped polysilicon.

Preferably, the high-resistance layer 14 is TiN.

Preferably, the high-resistance layer 14 is aluminum-doped TiN.

In the chip with the metal-oxide-metal capacitor of the present application, each metal capacitor area with the same requirements for functions and capacitances, as a metal capacitor unit, has the active area 11, the gate silicon oxide layer 12, the gate metal layer 13, the high-resistance layer 14 and the capacitor metal layer 15 with the same layout structure. In this way, the repeatability of a metal capacitor in the chip can be improved. Moreover, as shown in FIG. 5, by replacing an original irregular dummy pattern with the active area, the gate area and the high-resistance area which are regular, the metal capacitor area with the same requirements for functions and capacitances can invoke a dummy pattern area with the same requirements for functions and capacitances, which ensures the process uniformity, and can meet the process requirements of the active area and the gate area. Moreover, the physically floating high-resistance area (HiR) can shield unstable parasitic capacitors from the capacitor metal layer 15 to the substrate, such that the dummy pattern areas between the metal-oxide-metal capacitor and the active area have the same parasitic capacitors of Cp2′ at high voltage, and the uniformity of the parasitic capacitors when a high voltage is applied to the metal-oxide-metal capacitor is improved.

### BRIEF DESCRIPTION OF THE DRAWINGS

To more clearly illustrate the technical solution of the present application, figures used in the present application will be briefly introduced below. Obviously, the figures in the following description are only some embodiments of the present application, and other figures can be obtained from these figures for those of ordinary skill in the art, without the exercise of inventive effect.

FIG. 1a shows a current density-brightness curve of a white OLED;

FIG. 1b shows a degradation curve of current of a white OLED over time;

FIG. 1c shows a conventional drive current compensation circuit of a white OLED;

FIG. 2a shows a schematic diagram of a stack of multiple layers of metal of a capacitor metal layer of a 28 nm high-voltage OLED driver chip;

FIG. 2b shows a schematic diagram of capacitors within the same metal layer;

FIG. 3a shows a situation of a dummy pattern area of an existing metal capacitor area, with each area with the same requirements for functions and capacitances being different due to the difference in surrounding conditions.

FIG. 3b shows a situation of parasitic capacitors of an existing medium-voltage metal capacitor area;

FIG. 4 shows a schematic diagram of a structure of a metal capacitor area and a situation of parasitic capacitors of a chip with a metal-oxide-metal capacitor according to an embodiment of the present application; and

FIG. 5 shows a schematic diagram of a situation of a dummy pattern area of a metal capacitor area of a chip with a metal-oxide-metal capacitor according to an embodiment of the present application.

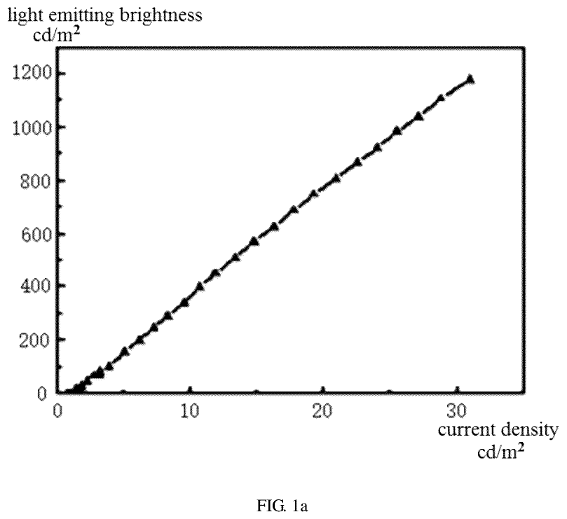

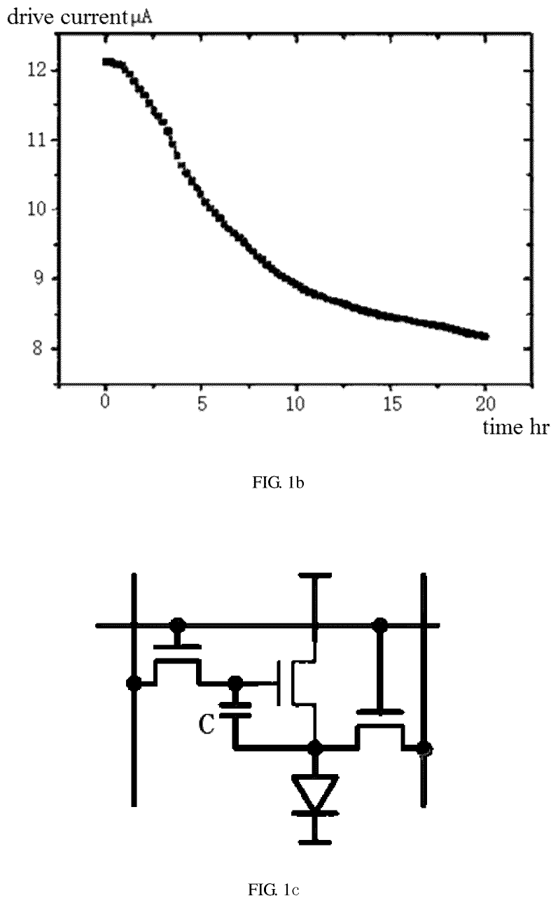

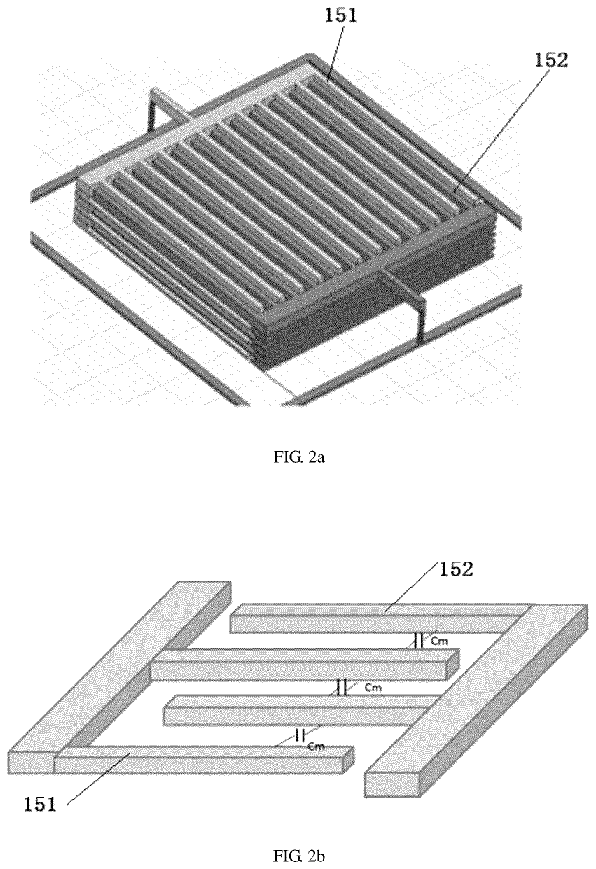

### DESCRIPTION OF REFERENCE SYMBOLS

11. active area; 12. gate oxide layer; 13. gate metal layer; 14. high-resistance layer; 15. capacitor metal layer; 151. left-finger metal strip; and 152. right-finger metal strip.

### DETAILED DESCRIPTION OF THE DISCLOSURE

Technical solutions in embodiments of the present application may be described clearly and completely below in conjunction with figures in the embodiments of the present application. Obviously, the described embodiments are only some of the embodiments of the present application, but not all of the embodiments. The scope of protection of the present application encompasses all other embodiments obtained by those of ordinary skill in the art based on the embodiments of the present application without the exercise of inventive effort.

Terms such as “first”, “second”, etc. in the present application do not indicate any order, number, or importance, but are only to distinguish different constituent parts. The phasing such as “including”, “comprising”, etc. means that an element or object preceded by the phasing encompasses an element or object and equivalents thereof listed below the phasing, but does not exclude other elements or objects. The expression such as “connected”, “coupled”, etc. is not limited to physical or mechanical connections, but may include direct or indirect electrical connections. Terms such as “upper”, “lower”, “left”, “right”, etc. are used only to indicate relative positional relations. When an absolute position of a described object is changed, the relative positional relation may be changed accordingly.

It should be noted that the embodiments of the present application and features in the embodiments may be combined with each other without contradictory.

### Embodiment I

A chip with a metal-oxide-metal capacitor includes at least two metal capacitor areas with the same requirements for functions and capacitances.

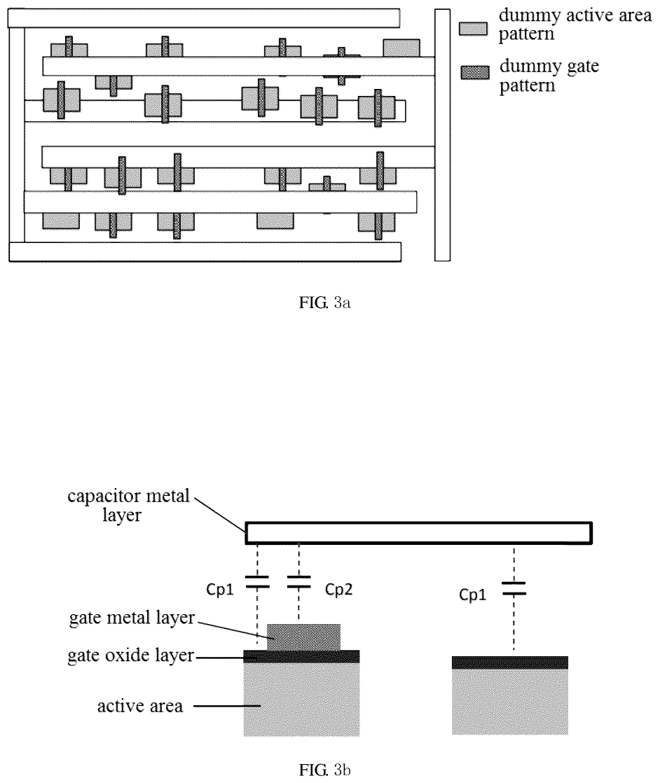

As shown in FIG. 4, for each metal capacitor area, a gate oxide layer 12, a gate metal layer 13, a high-resistance layer 14 and a capacitor metal layer 15 are sequentially formed on an active area 11 of a substrate from bottom to top; vertical projections of the active area 11, the gate oxide layer 12 and the gate metal layer 13 are located within a vertical projection of the high-resistance layer 14; and insulating medium layers are formed between the high-resistance layer 14 and the gate metal layer 13 and between the high-resistance layer 14 and the capacitor metal layer 15.

The resistivity of the high-resistance layer 14 is greater than that of the gate metal layer 13.

The resistivity of the high-resistance layer 14 is greater than that of the capacitor metal layer 15.

Preferably, the gate oxide layer 12 is silicon oxide.

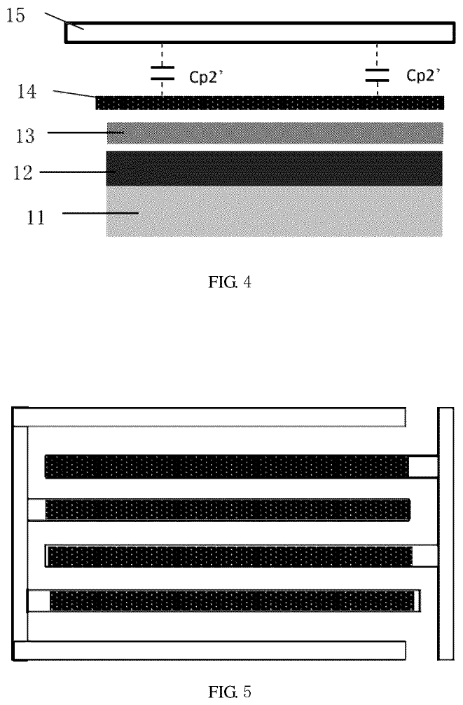

In the chip with the metal-oxide-metal capacitor of the embodiment I, each metal capacitor area with the same requirements for functions and capacitances, as a metal capacitor unit, has the active area 11, the gate silicon oxide layer 12, the gate metal layer 13, the high-resistance layer 14 and the capacitor metal layer 15 with the same layout structure. In this way, the repeatability of a metal capacitor in the chip can be improved. Moreover, as shown in FIG. 5, by replacing an original irregular dummy pattern with the active area, the gate area and the high-resistance area which are regular, the metal capacitor area with the same requirements for functions and capacitances can invoke a dummy pattern area with the same requirements for functions and capacitances, which ensures the process uniformity, and can meet the process requirements of the active area and the gate area. Moreover, the physically floating high-resistance area (HiR) can shield unstable parasitic capacitors from the capacitor metal layer 15 to the substrate, such that the dummy pattern areas between the metal-oxide-metal capacitor and the active area have the same parasitic capacitors of Cp2′ at high voltage, and the uniformity of the parasitic capacitors when a high voltage is applied to the metal-oxide-metal capacitor is improved.

### Embodiment II

Based on the embodiment I, the chip with the metal-oxide-metal capacitor is an OLED driver chip.

Preferably, the OLED driver chip is fabricated by using a 28 nm high-voltage (HV) (greater than 12V) process platform.

With the advancement of a process node of a logic device, an OLED mass production process node most advanced at present is combined with a 28 nm high-voltage (HV) metal gate (28hv metal gate) technology.

The chip with the metal-oxide-metal capacitor of the embodiment II can solve the problem of degradation of the performance of the OLED driver chip due to larger parasitic capacitors and non-uniformity of capacitances of the parasitic capacitors of the metal capacitor area with the same requirements for functions and capacitances for the drive current compensation in a 28 nm display driver circuit.

### Embodiment III

Based on the chip with the metal-oxide-metal capacitor of the embodiment I, the capacitor metal layer 15 includes at least one layer of metal stacked sequentially from top to bottom and insulated from each other.

Each layer of metal of the capacitor metal layer 15 includes a plurality of left-finger metal strips 151 and a plurality of right-finger metal strips 152.

The plurality of left-finger metal strips 151 and the plurality of right-finger metal strips 152 are interdigitated, left ends of the left-finger metal strips 151 are shorted together, and right ends of the right-finger metal strips 152 are shorted together for connecting the substrate.

Preferably, the capacitor metal layers 15 of the metal capacitor areas having the same capacitances are connected in parallel.

Preferably, the gate metal layer 13 is aluminum.

Preferably, the capacitor metal layer 13 is copper.

Preferably, the high-resistance layer 14 is polysilicon.

Preferably, the high-resistance layer 14 is P-doped polysilicon.

Preferably, the high-resistance layer 14 is TiN.

Preferably, the high-resistance layer 14 is aluminum-doped TiN.

The embodiments described above are only preferred embodiments of the present application and are not intended to limit the present application. The scope of protection of the present application shall include any modifications, equivalent substitutions, improvements, etc. made within the spirit and principles of the present application.

What is claimed is:

1. A chip with a metal-oxide-metal capacitor, comprising at least two metal capacitor areas with the same requirements for functions and capacitances;
for each metal capacitor area, a gate oxide layer, a gate metal layer, a high-resistance layer and a capacitor metal layer are sequentially formed on an active area of a substrate from bottom to top; vertical projections of the active area, the gate oxide layer and the gate metal layer are located within a vertical projection of the high-resistance layer; and insulating layers are formed between the high-resistance layer and the gate metal layer and between the high-resistance layer and the capacitor metal layer;
a resistivity of the high-resistance layer is greater than that of the gate metal layer; and
the resistivity of the high-resistance layer is greater than that of the capacitor metal layer.

2. The chip with the metal-oxide-metal capacitor according to claim 1, wherein the gate oxide layer is silicon oxide.

3. The chip with the metal-oxide-metal capacitor according to claim 1, wherein the chip is an organic light emitting diode (OLED) driver chip.

4. The chip with the metal-oxide-metal capacitor according to claim 3, wherein the OLED driver chip is fabricated by using a 28 nm high-pressure process platform.

5. The chip with the metal-oxide-metal capacitor according to claim 1, wherein
the capacitor metal layer comprises at least one layer of metal stacked sequentially from top to bottom and insulated from each other,
each layer of metal of the capacitor metal layer comprises a plurality of left-finger metal strips and a plurality of right-finger metal strips,
the plurality of left-finger metal strips and the plurality of right-finger metal strips are interdigitated, left ends of the left-finger metal strips are shorted together, and right ends of the right-finger metal strips are shorted together for connecting the substrate.

6. The chip with the metal-oxide-metal capacitor according to claim 1, wherein capacitor metal layers of the metal capacitor areas with the same capacitances are connected in parallel.

7. The chip with the metal-oxide-metal capacitor according to claim 1, wherein the gate metal layer is aluminum.

8. The chip with the metal-oxide-metal capacitor according to claim 1, wherein the capacitor metal layer is copper.

9. The chip with the metal-oxide-metal capacitor according to claim 1, wherein the high-resistance layer is polysilicon.

10. The chip with the metal-oxide-metal capacitor according to claim 1, wherein the high-resistance layer is P-doped polysilicon.

11. The chip with the metal-oxide-metal capacitor according to claim 1, wherein the high-resistance layer is TiN.

12. The chip with the metal-oxide-metal capacitor according to claim 1, wherein the high-resistance layer is aluminum-doped TiN.
